(19) United States
(12) Patent Application Publication
(10) Pub. No.: US 2013/0171811 A1
(43) Pub. Date: Jul. 4, 2013

(54) METHOD FOR MANUFACTURING COMPOUND SEMICONDUCTOR

(71) Applicant: PANASONIC CORPORATION, OSAKA (JP)

(72) Inventors: ASAMIRA SUZUKI, Osaka (JP); HIDEKAZU UMEDA, Osaka (JP); MASAHIRO ISHIDA, Osaka (JP); TETSUZO UEDA, Osaka (JP)

(73) Assignee: PANASONIC CORPORATION, Osaka (JP)

(21) Appl. No.: 13/776,934

(22) Filed: Feb. 26, 2013

Related U.S. Application Data
(63) Continuation of application No. PCT/JP2011/003045, filed on May 31, 2011.

(30) Foreign Application Priority Data
Sep. 1, 2010 (JP) 2010-196117

(51) Int. Cl. H01L 21/265

(52) U.S. Cl. CPC H01L 21/265
USPC 438/518

(57) ABSTRACT

In a method for manufacturing a compound semiconductor, a silicon oxide film is formed in an upper part of a substrate made of silicon. Subsequently, a base layer made of single crystal silicon to which ions are implanted is formed by performing ion implantation to a region of the substrate below the silicon oxide film and performing a thermal process. Then, the base layer is exposed by removing the silicon oxide film. Finally, a GaN layer is formed on the base layer.

### CROSS-REFERENCE TO RELATED APPLICATIONS

This is a continuation of International Application No. PCT/JP2011/003045 filed on May 31, 2011, which claims priority to Japanese Patent Application No. 2010-196117 filed on Sep. 1, 2010. The entire disclosures of these applications are incorporated by reference herein.

### BACKGROUND

The present disclosure relates to a method for manufacturing a compound semiconductor, and particularly relates to a method for manufacturing a compound semiconductor applicable to, e.g., a power device.

An III-V nitride semiconductor is a compound semiconductor represented by a general formula of B_{w}AlₓGa_{y}In_{z}N (where w+x+y+z=1, 0≦w≦1, 0≦x≦1, 0≦y≦1, and 0≦z≦1) and made of aluminum (Al), boron (B), gallium (Ga), and a compound of indium (In) and nitrogen (N).

An III-V nitride semiconductor as represented by gallium nitride (GaN) has a large band gap, and such a large band gap results in advantages such as high breakdown voltage, high electron saturation velocity, high electron mobility, and a high electron concentration in the case where a heterojunction is formed. Thus, emphasis has been placed on development of III-V nitride semiconductors for the purpose of application to, e.g., short-wavelength light emitting elements, high-output high-frequency elements, high-frequency low-noise amplifying elements, and high-output switching elements.

In recent years, study has been conducted to use a substrate made of, e.g., silicon (Si) as a substrate forming a semiconductor device using an III-V nitride semiconductor. A size of a silicon substrate is easily enlargeable. If a silicon substrate is used as a substrate on which an III-V nitride semiconductor grows, a cost for a semiconductor device can be significantly reduced.

Typically, in the case where an III-V nitride semiconductor is formed on a silicon substrate, since there is a significant difference in lattice constant and coefficient of thermal expansion between silicon and a nitride semiconductor, it is difficult to form, with good crystallizability, an III-V nitride semiconductor on a silicon substrate.

Conventionally, in a photoelectric device operated with light having short waves or a GaN power device operated at a high current density, a sapphire substrate has been broadly used for epitaxial growth of GaN. However, there is a high technical barrier in the cost reduction and the enlargement of the size of the substrate, and a practical substrate choice cannot be made particularly in terms of the cost reduction.

Since silicon carbide (SiC) has a smaller lattice mismatch and higher thermal conductivity as compared to that of a sapphire substrate, silicon carbide has been highly expected as a material of a substrate for a GaN power device. However, it has been known that there are the following disadvantages: bulk silicon carbide is extremely expensive; and it is difficult to form a large wafer from silicon carbide (see, e.g., “Prospect and Aspect of the Research on Wide Bandgap Semiconductor Devices,” Tadashi Yoshida, Bulletin of the Electrotechnical Laboratory, Vol. 62, Nos. 10 and 11, pp. 575-586 (1998)).

For example, Japanese Patent Publication No. 2005-203666 describes a method for manufacturing an inexpensive high-performance III-V nitride semiconductor by implanting carbon (C) ions to an inexpensive-silicon substrate whose size is easily enlargeable to form a SiC layer as an intermediate layer and then forming, on the intermediate layer, a high-quality III-V nitride semiconductor having small residual stress.

### SUMMARY

However, it is necessary to implant an extremely-large amount of carbon ions to carbonate silicon into silicon carbide. In the conventional method described in Japanese Patent Publication No. 2005-203666, a dose of 1×10¹⁷ ions/cm² is required. For practical purposes, it is technically difficult not only to implement this method within a practical cost but also to perform a thermal process to realize single crystallization at a surface of a substrate made of silicon having a crystal lattice disarranged by implanting a high dose of ions.

The present disclosure has been made in view of the foregoing, and aims to form, on an inexpensive-silicon substrate whose size is easily enlargeable, a high-quality compound semiconductor having small residual stress.

In order to accomplish the foregoing, a semiconductor film is formed on a base layer made of single crystal silicon to which ions are implanted in a method for manufacturing a compound semiconductor according to the present disclosure.

Specifically, the method for manufacturing a compound semiconductor according to the present disclosure includes a step (a) of forming a silicon oxide film in an upper part of a substrate made of silicon; a step (b) of forming, by performing ion implantation to a region of the substrate below the silicon oxide film and performing a thermal process, a base layer made of single crystal silicon to which ions are implanted; a step (c) of exposing the base layer by removing the silicon oxide film; and a step (d) of forming a semiconductor film on the base layer.

According to the method of the present disclosure, the ion implantation and the thermal process are performed to form the based layer made of single crystal silicon to which ions are implanted in the inexpensive-silicon substrate whose size is easily enlargeable. Thus, a high-quality compound semiconductor layer having small residual stress can be formed on the substrate.

In the method of the present disclosure, the ion implantation is preferably performed with acceleration energy of equal to or less than 100 keV.

In the method of the present disclosure, the ion implantation is preferably performed at a dose rate of equal to or greater than 1×10¹³ ions/cm² and equal to or less than 1×10¹⁶ ions/cm².

In the method of the present disclosure, the thermal process is preferably performed at a temperature of equal to or greater than 1000° C. in inert gas atmosphere.

In the method of the present disclosure, the semiconductor film is preferably made of AlₓGa_{y}In_{z}N where x+y+z=1, 0≦x≦1, 0≦y≦1, and 0≦z≦1.

The method of the present disclosure preferably further includes, before the step (d), a step (d1) of forming at least one buffer layer on the base layer.

In such a case, one of the at least one buffer layer contacting the base layer is preferably made of aluminum nitride.

If the at least one buffer layer includes two or more buffer layers, one of the two or more buffer layers contacting the semiconductor film is preferably made of AlₓGa_{y}In_{z}N where x+y+z=1, 0≦x≦1, 0≦y≦1, and 0≦z≦1.

In the method of the present disclosure, ions used for the ion implantation are preferably boron ions or phosphorus ions.

In the method of the present disclosure, ions used for the ion implantation may be boron ions, and a dose distribution of the ions may have a highest value at a position within a range of 100 nm from a surface of the substrate in a depth direction thereof.

In the method of the present disclosure, the ion implantation is preferably performed for part of the surface of the substrate.

As described above, according to the method of the present disclosure, a high-quality compound semiconductor layer having small residual stress can be formed on an inexpensive-silicon substrate whose size is easily enlargeable.

### BRIEF DESCRIPTION OF THE DRAWINGS

FIG. 1 is a cross-sectional view illustrating a compound semiconductor manufactured by a method for manufacturing a compound semiconductor according to an embodiment of the present disclosure.

FIG. 2 is a graph illustrating results on X-ray diffraction in a GaN layer formed on a base layer.

FIG. 3 is a SEM image of a surface of a GaN layer formed on a base layer by performing ion implantation in which a dose of each of B ions and P ions is 5×10¹⁵ ions/cm² and a thermal process.

FIG. 4 is a SEM image of a surface of a GaN layer formed on a base layer by performing ion implantation in which a dose of each of B ions and P ions is 1×10¹⁴ ions/cm² and a thermal process.

FIG. 5 is a SEM image of a surface of a GaN layer formed on an ion implantation layer in the case where ion implantation in which a dose of each of B ions and P ions is 5×10¹⁵ ions/cm² is performed and a thermal process is not performed.

FIG. 6 is a graph illustrating dependency of a dose of ions upon ion implantation on a half width obtained by diffraction in a GaN layer whose surface has a surface orientation of (10-12).

### DETAILED DESCRIPTION

### Embodiment of the Present Disclosure

A method for manufacturing a compound semiconductor according to an embodiment of the present disclosure will be described. In the present embodiment, an III-V nitride semiconductor is used as an example of the compound semiconductor.

First, a silicon oxide film (SiO₂ film) is formed in an upper part of a substrate made of single crystal silicon (Si). The SiO₂ film is formed by performing a thermal process in the upper part of the substrate. The SiO₂ film is formed so that a control of an ion dose distribution in a depth direction from a surface of the substrate is facilitated in later-performed ion implantation to the substrate. In particular, the SiO₂ film is essential upon implantation of boron (B) ions, and allows a control of a distribution of B ions in the depth direction. Several reports have been made on implantation of B ions to a substrate made of silicon, and action of B ions in the substrate has been recently known. Particularly in the case of implantation of B ions, a phenomenon has been known, in which B ions are, due to a thermally-oxidized film, attracted toward the thermally-oxidized film (see, e.g., “B Diffusion and Clustering in Ion Implanted Si: The Role of B Cluster Precursors,” L. Pelaz et al., Applied Physics Letters, 70(17)).

That is, an ion implantation profile after the ion implantation and the thermal process varies depending on the presence or absence of the SiO₂ film. In order to form a highest implanted ion concentration region within a range of 100 nm from the surface of the substrate in the depth direction, it is preferable that the thermally-oxidized film is formed, and that the ion implantation and the thermal process for repairing damage are performed.

In order to efficiently distribute a high concentration of ionic species on the substrate after removal of the SiO₂ film, the SiO₂ film preferably has a thickness of equal to or greater than about 10 nm and equal to or less than about 150 nm, and is preferably formed at a temperature of about 900° C. in oxygen atmosphere.

Next, e.g., B ions or P ions are implanted to the silicon substrate, thereby forming an ion implantation layer in the upper part of the substrate. In order to reduce sputtering-etching of the substrate by ions, acceleration energy upon the implantation of B ions or P ions is preferably equal to or less than about 100 keV. At this point, it is not necessary to heat the substrate. The implantation of B ions or P ions is preferably performed in vacuum atmosphere of equal to or less than about 10⁻³ Pa in order to suppress accelerated ion energy to a small dispersion range.

According to the foregoing ion implantation, an advantage in that warpage and cracking of the substrate are reduced can be realized not only by implanting ions to the entirety of the substrate, but also by implanting ions to part of the substrate to form an implantation region and forming both of B-ion and P-ion implantation regions.

Next, the thermal process is performed for the substrate to which B ions or P ions are implanted, thereby forming a base layer from the ion implantation layer. The base layer is made of single crystal silicon to which ions are implanted. As a temperature condition for the thermal process, a temperature should be at such a degree that damage caused due to ion species implanted to the substrate can be repaired. The thermal process is preferably performed at a temperature of equal to or greater than about 1000° C. and equal to or less than about 1200° C.

As an atmosphere condition for the thermal process, the thermal process is preferably performed in nitrogen atmosphere. Note that other type of inert gas may be used. In addition, the thermal process is performed for about 0.5-3 hours, and preferably about 1-2 hours.

In the foregoing manner, the ion implantation to the silicon substrate and the damage repairing are performed. However, for epitaxial growth of the III-V nitride semiconductor, it is necessary that a clean surface of the substrate for which damage is repaired is exposed. That is, since unnecessary layers such as the SiO₂ film remain on the surface of the substrate during the foregoing process, it is necessary to remove such layers. Thus, the unnecessary layers, such as the SiO₂ film, remaining on the base layer uniformly formed in the substrate are removed, thereby exposing the base layer.

For etching of the SiO₂ film and a Si layer formed on the base layer, wet etching is preferably performed by using, e.g., buffered hydrogen fluoride (BHF) containing 15% of hydrofluoric acid (HF).

Next, e.g., an AlN buffer layer, an AlGaN buffer layer, and a semiconductor film made of GaN are formed in this order on the exposed base layer. Such layers are preferably formed by using metal organic chemical vapor deposition (MOCVD). Conditions for forming the foregoing layers will be described below.

First, in the state in which a reactor of a MOCVD device is in hydrogen gas atmosphere, a temperature is increased at a temperature increase rate of about 50-150° C./min until the temperature reaches a temperature range of about 1100-1300° C. In the state in which the foregoing temperature is maintained for about 1-30 minutes, a base layer is cleaned with heat in the hydrogen gas atmosphere. A surface of the base layer is cleaned by such processing.

Next, in the state in which the temperature inside the reactor is maintained at about 1100-1300° C., e.g., a gas mixture of trimethylaluminium (TMA) and ammonia (NH₃) is supplied to the reactor as a gas source for a growth reaction of AlN. In order to form a buffer layer having a suitable thickness, an AlN buffer layer is formed in the state in which the foregoing temperature is maintained for about 1-15 minutes. A pressure upon crystal growth in the reactor is preferably about 6.67−9.33 kPa.

Next, the temperature inside the reactor reaches a temperature of about 1150-1250° C. which is suitable for growth of an AlGaN buffer layer. At this point, the temperature changes at about 50-100° C./min. Then, e.g., a gas mixture of trimethylgallium (TMG), trimethylaluminium (TMA), and ammonia (NH₃) is supplied to the reactor as a gas source for a growth reaction of AlGaN. In order to form a buffer layer having a suitable thickness, an AlGaN buffer layer is formed in the state in which the foregoing temperature is maintained for about 1-15 minutes.

After the AlGaN buffer layer is formed, a supply of ammonia gas continues while the temperature inside the reactor is decreased at a temperature decrease rate of about 50-100° C./min until the temperature reaches about 1000-1200° C. which is suitable for growth of a GaN layer. Then, e.g., a gas mixture of trimethylgallium (TMG) and ammonia (NH₃) is supplied to the reactor as a gas source for a growth reaction of GaN, thereby growing a GaN layer to a suitable thickness. A time period for maintaining the foregoing temperature depends on the required thickness of the GaN layer, and is about 0.5-3 hours to form a GaN layer having a thickness of about 1-5 μm.

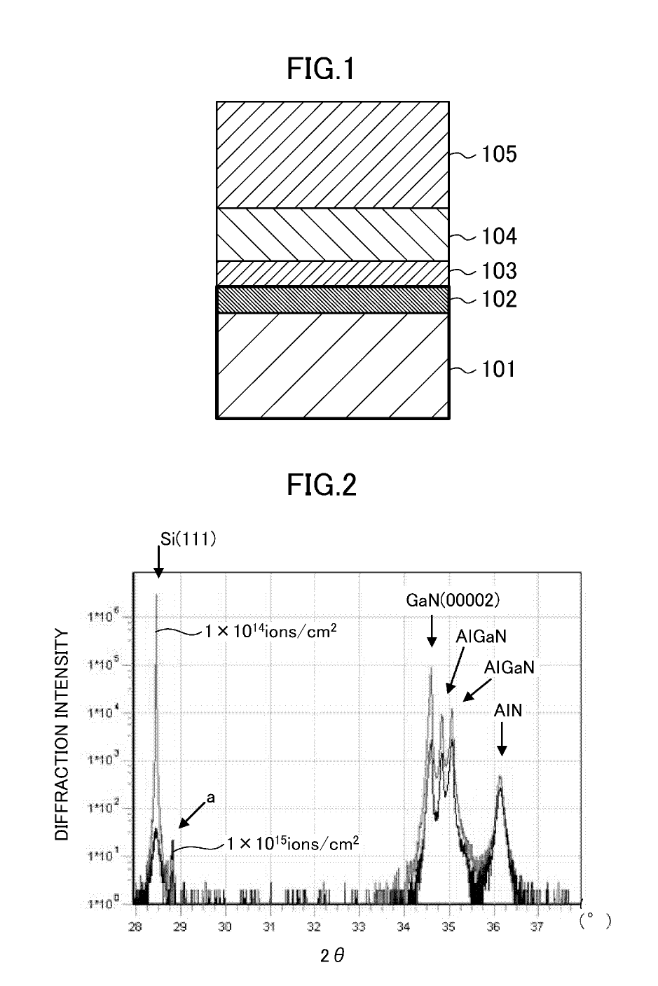

According to the foregoing process, a base layer 102 made of single crystal silicon to which ions are implanted is, referring to FIG. 1, formed in an upper part of a substrate 101 made of silicon. An AlN buffer layer 103 and an AlGaN buffer layer 104 are formed in this order on the base layer 102, and a stress-free, crack-free single crystal GaN layer 105 is formed on the AlGaN buffer layer 104.

In the present embodiment, the buffer layers are formed, and the GaN layer is formed on the buffer layer. However, a GaN layer may be formed on a base layer without forming a buffer layer. Alternatively, if needed, only an AlN buffer layer may be formed, and an AlGaN buffer layer may not be necessarily formed. The present embodiment describes the case where the MOCVD is used. However, molecular beam epitaxy (MBE) using plasma-activated nitrogen as a nitrogen source may be used.

The ion implantation of the present embodiment is not necessarily performed for the entirety of the substrate, and the advantage is available even by partial implantation, i.e., a patterned implantation method. In such a case, ion implantation regions cover at least about 20% of the entirety of a wafer, and preferably about 30% of the entirety of the wafer. Such regions are not necessarily continuous. Regions may be distributed in a concentric pattern, in a grid pattern, or in such a pattern that many regions each having a size of equal to or greater than 1 μm² are scattered.

According to the compound semiconductor manufacturing method of the embodiment of the present disclosure, a high-quality compound semiconductor layer having small residual stress can be formed on an inexpensive-silicon substrate whose size is easily enlargeable.

### Example

An example of the compound semiconductor manufacturing method of the present disclosure will be described. In the present example, an III-V nitride semiconductor is used as an example of the compound semiconductor.

First, in oxygen (O₂) atmosphere, thermal oxidation is performed such that the temperature of a substrate made of single crystal silicon whose principal surface has a surface orientation of (111) reaches 900° C. In such a manner, a silicon oxide film (SiO₂ film) is formed to 50 nm in an upper part of the substrate.

Next, B ions are implanted to the substrate under the following conditions: no heating for the substrate; acceleration voltage of 40 keV; an implantation angle of 7°; a rotation angle of 23′; vacuum atmosphere of 10⁻⁴ Pa around the substrate; and an implanted B-ion does rate of 1×10¹⁵ ions/cm². Under such conditions, a B-ion implantation layer is formed near a surface of the substrate.

Next, a thermal process is performed for the substrate to which B ions are implanted, thereby forming a base layer from the B-ion implantation layer formed near the surface of the substrate. The base layer is made of single crystal silicon to which ions are implanted. The thermal process is performed at 1100° C. for 1 hour in nitrogen atmosphere.

Next, unnecessary layers formed on the base layer, such as a SiO₂ film or Si layer, are removed by wet etching using, e.g., a buffered hydrogen fluoride (BHF) etching solution containing 15% of hydrofluoric acid (HF). In such a manner, the base layer is exposed.

Next, an AlN buffer layer, an AlGaN buffer layer, and a GaN layer are formed in this order on the exposed base layer by using metal organic chemical vapor deposition (MOCVD). Specifically, in the state in which a reactor of a MOCVD device is in hydrogen gas atmosphere, the temperature of the substrate is increased at a temperature increase rate of about 100° C./min, and the substrate is held at 1250° C. for 1 minute. As a result, a surface of the base layer is cleaned in the heated hydrogen gas atmosphere. Subsequently, in the state in which the temperature inside the reactor is maintained at 1250° C., a gas mixture of trimethylaluminium (TMA) and ammonia (NH₃) is supplied to the reactor as a gas source for a growth reaction of AlN by using hydrogen as carrier gas. In such a manner, a growth reaction of an AlN layer is performed such that the AlN layer has a suitable thickness as a buffer layer. Subsequently, a gas mixture of trimethylgallium (TMG), trimethylaluminium (TMA), and ammonia is supplied by using hydrogen as carrier gas, resulting in growth of an epitaxial layer made of AlGaN. Next, a gas mixture of TMG and ammonia is supplied by using hydrogen as carrier gas, resulting in growth of an epitaxial layer having a thickness of 1 μm and made of GaN. After the growth reaction of the epitaxial layer made of GaN, only a supply of ammonia gas continues while the temperature inside the reactor is decreased at a temperature decrease rate of 100° C./min. Finally, after the supply of ammonia gas is stopped, the temperature inside the reactor is further decreased to complete the reaction.

Results on characteristic evaluation performed, by X-ray diffraction, for a GaN layer formed on a base layer with an AlN buffer layer and an AlGaN buffer layer being interposed therebetween and having a thickness of 1 μm will be described. The case where the dose of B ions for forming the base layer is 1×10¹⁴ ions/cm² and the case where the dose of B ions is 1×10¹⁵ ions/cm² are compared to each other. Referring to FIG. 2, diffraction peaks due to the epitaxial layers made of GaN, AlGaN, and AlN are similar between both cases regardless of variation in dose of B ions, and there is no significant difference in crystallizability evaluated by the X-ray diffraction. Damage caused by ion implantation is sufficiently repaired by a thermal process, and it can be confirmed that the GaN layer is formed in good condition.

On the other hand, a peak due to a substrate made of silicon shows a change depending on the dose of B ions. The peak due to the silicon substrate is decreased as the dose increases, and there is another peak corresponding to a different lattice constant near the foregoing peak (“a” in FIG. 2).

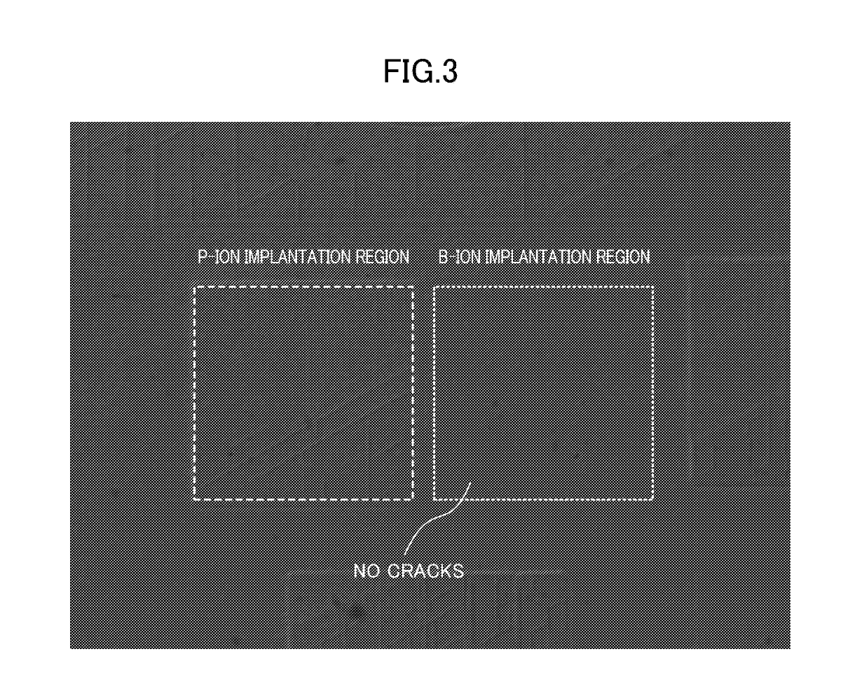

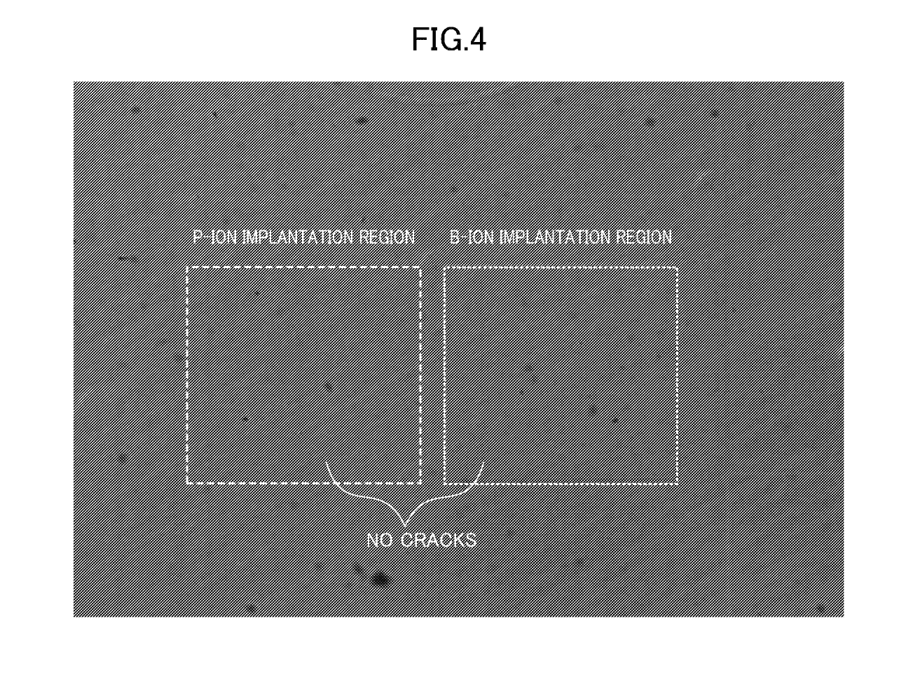

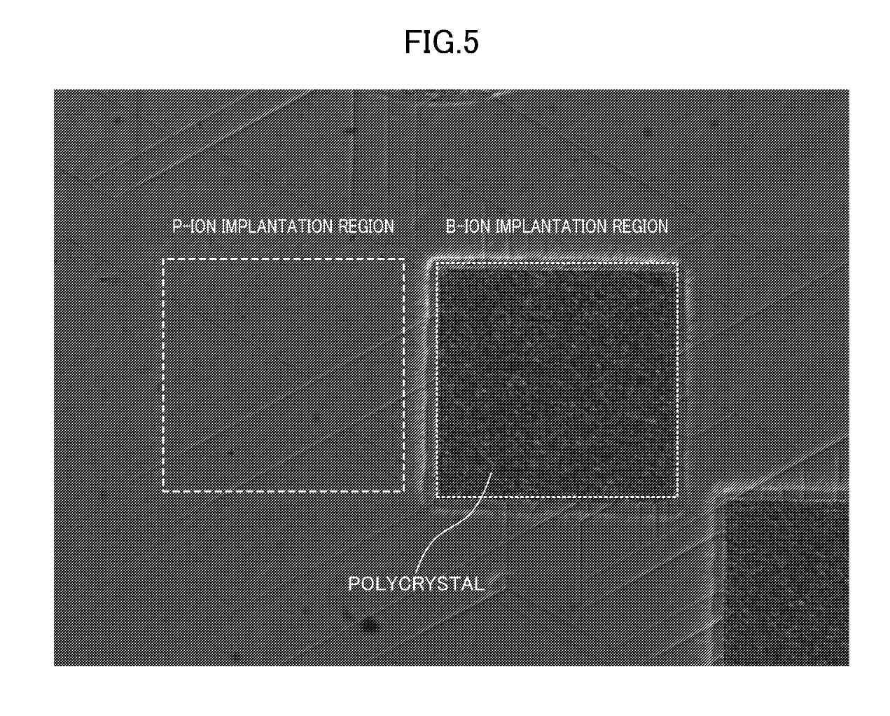

Next, results on characteristic evaluation performed by observing, with a scanning electron microscope (SEM), a surface of a GaN layer having a thickness of 1 μm and formed on a base layer for which ion implantation and a thermal process are performed under the following conditions or on an ion implantation layer for which only the ion implantation is performed with an AlN buffer layer and an AlGaN buffer layer being interposed therebetween will be described. The conditions for the ion implantation are that a dose of ions is 5×10¹⁵ ions/cm² or 1×10¹⁴ ions/cm², and a P-ion implantation region and B-ion implantation region are formed in the same substrate. Referring to FIG. 3, if a B-ion dose of 5×10¹⁵ ions/cm² and a P-ion dose of 5×10¹⁵ ions/cm² are implanted, cracking occurs in the P-ion implantation region. Referring to FIG. 4, if a B-ion dose of 1×10¹⁴ ions/cm² and a P-ion dose of 1×10¹⁴ ions/cm² are implanted, no cracking occurs in both regions. If the thermal process for repairing damage of the substrate is not performed, when a B-ion dose of 5×10¹⁵ ions/cm² and a P-ion dose of 5×10¹⁵ ions/cm² are implanted, cracking occurs in the P-ion implantation region referring to FIG. 5. In addition, in the B-ion implantation region, epitaxial growth does not occur, resulting in polycrystallization.

The observation using the SEM shows that a limit value for the ion implantation is different between the P-ion implantation and the B-ion implantation. It is confirmed that a good film quality of an III-V nitride semiconductor grown on the substrate made of Si is maintained by performing the thermal process for repairing damage of the substrate, and cracking is reduced at a surface of the III-V nitride semiconductor.

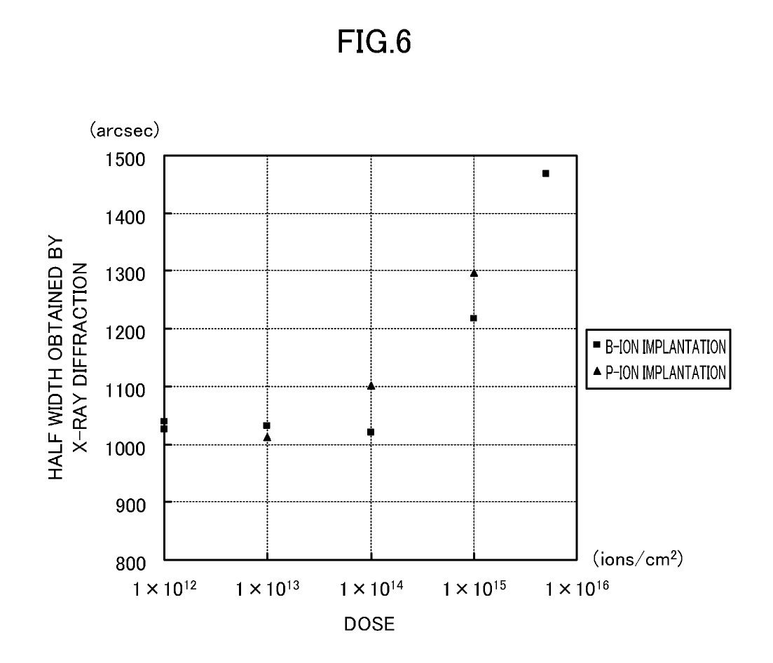

Next, a half width obtained by diffraction in a GaN layer having a thickness of 1 μm, having a surface with a surface orientation of (10-12), and formed on a base layer to which P ions or B ions are implanted with an AlN buffer layer and an AlGaN buffer layer being interposed therebetween will be described. Referring to FIG. 6, in the case of the P-ion implantation, the half width is increased depending on an implantation dose. When the dose is 1×10¹⁵ ions/cm², the half width reaches about 1300 seconds. This shows, in combination with the results on the observation using the SEM, that the implantation reaches its limitation when the dose is 1×10¹⁵ ions/cm².

On the other hand, in the case of the B-ion implantation, the half width tends not to significantly increase until the dose reaches 1×10¹⁵ ions/cm², and therefore good crystallizability can be maintained. In the case of a dose of 5×10¹⁵ ions/cm², the result on the observation using the SEM shows that no cracking occurs, but the half width reaches about 1500 seconds. This shows that the implantation reaches its limitation when the dose is 5×10¹⁵ ions/cm².

A series of results on the observation using the SEM shows that ions are not necessarily implanted to the entirety of the substrate, and cracking can be reduced or prevented by implanting ions only to any region of the substrate.

Based on the foregoing results, it is confirmed that the GaN layer of the present disclosure formed on the base layer has excellent crystallizability and has no cracks.

In the present example, the GaN layer has been described as an example of the epitaxial layer, and the AlGaN layer has been described as an example of the buffer layer contacting the GaN layer. However, the foregoing advantages can be realized by, in addition to the foregoing, a nitride semiconductor made of, e.g., indium nitride (InN), aluminum nitride (AlN), or an alloy (GaInN, GaAlN, InAlN, or GaInAlN) of at least two of gallium nitride, indium nitride, and aluminum nitride.

According to the compound semiconductor manufacturing method of the example of the present disclosure, many crystal defects caused in the silicon substrate due to the ion implantation are reduced by the thermal process, and therefore a high-quality ion implantation layer is formed in the upper part of the substrate. Thus, a primary elastic constant of the silicon substrate is changed. This relieves thermal stress corresponding to a difference in coefficient of thermal expansion between the base layer and, e.g., the GaN semiconductor layer, and therefore the GaN semiconductor layer formed on the base layer can be grown in a residual stress-free state. As a result, a high-quality compound semiconductor layer having small residual stress can be formed on an inexpensive-silicon substrate whose size is easily enlargeable. In addition, a high-performance compound semiconductor device can be formed on the compound semiconductor layer.

As described above, since a high-quality compound semiconductor layer having small residual stress can be formed on an inexpensive-silicon substrate whose size is easily enlargeable, the compound semiconductor manufacturing method of the present disclosure is useful for, e.g., a compound semiconductor manufacturing method applicable to, e.g., a power device.

What is claimed is:

1. A method for manufacturing a compound semiconductor, the method comprising:
a step (a) of forming a silicon oxide film in an upper part of a substrate made of silicon;
a step (b) of forming, by performing ion implantation to a region of the substrate below the silicon oxide film and performing a thermal process, a base layer made of single crystal silicon to which ions are implanted;
a step (c) of exposing the base layer by removing the silicon oxide film; and
a step (d) of forming a semiconductor film on the base layer.

2. The method of claim 1, wherein
the ion implantation is performed with acceleration energy of equal to or less than 100 keV.

3. The method of claim 1, wherein
the ion implantation is performed at a dose rate of equal to or greater than 1×10¹³ ions/cm² and equal to or less than 1×10¹⁶ ions/cm².

4. The method of claim 1, wherein
the thermal process is performed at a temperature of equal to or greater than 1000° C. in inert gas atmosphere.

5. The method of claim 1, wherein
the semiconductor film is made of AlₓGa_{y}In_{z}N where x+y+z=1, 0≦x≦1, 0≦y≦1, and 0≦z≦1.

6. The method of claim 1, further comprising:
before the step (d), a sub-step (d1) of forming at least one buffer layer on the base layer as part of the semiconductor film.

7. The method of claim 6, wherein
one of the at least one buffer layer contacting the base layer is made of aluminum nitride.

8. The method of claim 6, wherein
if the at least one buffer layer includes two or more buffer layers, one of the two or more buffer layers contacting the semiconductor film is made of AlₓGa_{y}In_{z}N where x+y+z=1, 0≦x≦1, 0≦y≦1, and 0≦z≦1.

9. The method of claim 1, wherein
ions used for the ion implantation are boron ions or phosphorus ions.

10. The method of claim 1, wherein
ions used for the ion implantation are boron ions, and a dose distribution of the ions has a highest value at a position within a range of 100 nm from a surface of the substrate in a depth direction thereof.

11. The method of claim 1, wherein
the ion implantation is performed for part of the surface of the substrate.
